(19) United States
(12) Patent Application Publication
(10) Pub. No.: US 2025/0046678 A1
(43) Pub. Date: Feb. 6, 2025

(54) SEMICONDUCTOR STRUCTURE WITH BACKSIDE THROUGH SUBSTRATE THERMAL CONDUCTIVE VIAS

(71) Applicant: Taiwan Semiconductor Manufacturing Company, Ltd., Hsin-Chu (TW)

(72) Inventors: Tsung-Chieh Hsiao, Changhua County (TW); Ke-Gang Wen, Hsinchu County (TW); Yu-Bey Wu, Hsinchu City (TW); Liang-Wei Wang, Hsinchu City (TW)

(21) Appl. No.: 18/406,836

(22) Filed: Jan. 8, 2024

Related U.S. Application Data
(60) Provisional application No. 63/517,375, filed on Aug. 3, 2023.

(51) Int. Cl. H01L 23/48; H01L 21/768; H01L 23/00; H01L 23/367; H01L 23/498; H01L 23/528; H01L 25/065

(52) U.S. Cl. CPC H01L 23/481; H01L 21/76898; H01L 23/367; H01L 23/49838; H01L 23/5286; H01L 24/08; H01L 25/0657; H01L 2224/08145; H01L 2225/06541; H01L 2225/06589; H01L 2924/1306

(57) ABSTRACT

A method includes receiving a workpiece including a device layer disposed on a frontside of the workpiece, forming a frontside interconnect structure over the device layer, attaching a carrier substrate over the frontside interconnect structure, and etching from a backside of the workpiece to form first trenches and second trenches. The first trenches extend partially into the carrier substrate for a distance less than the second trenches. The method also includes forming a plurality of first conductive features in the first trenches and a plurality of second conductive features in the second trenches, forming a backside interconnect structure covering the first conductive features and the second conductive features, and thinning the carrier substrate from the frontside of the workpiece to expose the second conductive features. The first conductive features remain partially embedded in the carrier substrate.

### PRIORITY DATA

This is a non-provisional application and claims benefit of U.S. Provisional Patent Application Ser. No. 63/517,375, filed Aug. 3, 2023, the entire disclosure of which is incorporated herein by reference.

### BACKGROUND

The semiconductor integrated circuit (IC) industry has experienced rapid growth. Continuing advances in semiconductor manufacturing processes have resulted in integrated circuits (“ICs”) having semiconductor devices with finer features and/or higher degrees of integration. Functional density (i.e., the number of interconnected devices per IC chip area) has generally increased while feature size (i.e., the smallest component that can be created using a fabrication process) has decreased. This scaling-down process generally has generally provided benefits by increasing production efficiency and lowering associated costs.

Advanced IC packaging technologies have been developed to further reduce density and/or improve performance of ICs, which are incorporated into many electronic devices. For example, IC packaging has evolved, such that multiple ICs may be vertically stacked in so-called three-dimensional (“3D”) IC packages. Heat dissipation is a challenge in the 3DIC packages because a 3D structure with increased chip density can exhibit high heat density and poor thermal dissipation performance. The heat generated in the inner die(s) of a 3D structure may be trapped in an inner region of a stacked structure and cause a sharp local temperature peak, sometimes referred to as a thermal hotspot. Thermal hotspots due to heat generated by devices may negatively affect the electrical performance of other overlaying devices in the stacked structure and often lead to electromigration and reliability issues for the 3D IC packages. Therefore, there is a need to solve or mitigate the above deficiencies and problems.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1 is a flow chart of a method for forming a semiconductor structure including thermal conductive through-substrate vias (TSVs) extending from the backside of an IC die, according to one or more aspects of the present disclosure.

FIGS. 2, 3, 4, 5, 6, 7, 8, 9, 10, and 11 illustrate fragmentary cross-sectional views of a workpiece during a fabrication process according to the method of FIG. 1, according to one or more aspects of the present disclosure.

FIG. 12 is a flow chart of another method for forming a semiconductor structure including thermal conductive through-substrate vias (TSVs) extending from the backside of an IC die, according to one or more aspects of the present disclosure.

FIGS. 13, 14, 15, 16, 17, 18, and 19 illustrate fragmentary cross-sectional views of a workpiece during a fabrication process according to the method of FIG. 12, according to one or more aspects of the present disclosure.

FIG. 20 is a flow chart of yet another method for forming a semiconductor structure including thermal conductive through-substrate vias (TSVs) extending from the backside of an IC die, according to one or more aspects of the present disclosure.

FIGS. 21, 23, 24, 25, and 26 illustrate fragmentary cross-sectional views of a workpiece during a fabrication process according to the method of FIG. 12, according to one or more aspects of the present disclosure.

FIG. 22 illustrates a top view of a heat dissipation layer, according to one or more aspects of the present disclosure.

FIG. 27 illustrates a diagram of a system-on-chip (SoC) package including thermal conductive TSVs, according to one or more aspects of the present disclosure.

### DETAILED DESCRIPTION

The present disclosure relates generally to integrated circuit (IC) packaging, and more particularly, to enhanced through via structures for semiconductor devices with backside interconnect structures.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

The present disclosure is generally related to the implementation of through-substrate (also termed as “through-silicon”) vias (TSVs) extending from a backside interconnect structure of an integrated circuit (IC) die to quickly dissipate heat generated by one or more thermal hotspot regions in an IC structure. In more detail, an IC structure may include one or more IC dies. These IC dies may contain electrical circuitries (comprised of transistors such as planar transistors, FinFET devices, or Gate-All-Around (GAA) devices) configured to perform various types of operations, such as processing computer instructions, storing data, transmit and/or receive electrical signals, detect radiation (e.g., visible light), sense biometric data, etc.

Thermal energy in the form of heat may be generated during the operations of the electrical circuitries, and some types of electrical circuitries may generate more heat than other types of electrical circuitries. When the heat-generating electrical circuitries are closely packed together on an IC die, one or more thermal hotspot regions may be formed. These thermal hotspot regions may refer to regions or areas on an IC die where more heat is generated per unit area/volume per unit time than other regions of the IC die. For example, a thermal hotspot region may have a greater temperature than a region that neighbors the thermal hotspot region during the operation of the IC die. Thermal hotspots are easily formed in a backside interconnect structure of an IC die, as there are less thermal dissipation paths available on the backside of an IC dic.

Conventionally, semiconductor devices are built in a stacked-up fashion, having transistors at the lowest level (a device layer) and a frontside interconnect structure (contacts, vias, and metal lines) on top of the transistors to provide connectivity to the transistors. Power rails (such as metal lines for voltage sources and ground planes) are also above the transistors and may be part of the interconnect structures. As the integrated circuits continue to scale down, so do the power rails. This inevitably leads to increased voltage drop across the power rails, as well as increased power consumption of the integrated circuits. Other than power rails, signal lines also suffer from such scaling down, such as the ever-reduced signal line pitches that leads to increased parasitic capacitance and reduced circuit speed. To address this challenge, a backside interconnect structure including power rails and/or signal lines, and vias formed on the backside of an IC, may be implemented to alleviate some metal routing burden from the frontside interconnect structure and reduce resistance and parasitic capacitance thereof. However, the backside interconnect structure generally uses a low-k or extreme low-k (ELK) dielectric materials, which generally has poor thermal conductivity and leads to thermal hotspot regions formed at the backside of an IC dic.

If the heat generated by the thermal hotspot regions is not quickly dissipated, then the performance of the IC die may be degraded. For example, a computer processor (as a form of IC die or IC chip) may begin to slow down. As another example, an IC device may consume an excessive amount of power when it operates under an elevated temperature environment. In addition, the excessive amount of heat may shorten the lifespan or degrade the durability of the IC die or IC chip. Therefore, a more satisfactory solution to quickly and efficiently dissipate the heat generated by the thermal hotspot regions may be needed.

To address this problem, the present disclosure implements a plurality of through-substrate (or termed as “through-silicon”) thermal conductive vias, also referred to as thermal conductive TSVs, in different regions of the IC structure, as well as a plurality of power/signal TSVs. The thermal conductive TSVs and power/signal TSVs are both compatible with the process flow of the backside interconnect structure of the IC structure. The thermal conductive TSVs extend from one of the interconnect layers of the backside interconnect structure and extend upwardly through the device layer and the frontside interconnect structure of the IC structure. The power/signal TSVs extend from one of the interconnect layers of the backside interconnect structure and extend upwardly through the device layer and the frontside interconnect structure of the IC structure. The thermal conductive TSVs and power/signal TSVs may extend from the same backside interconnect layer or different backside interconnect layers. The thermal conductive TSVs may be allocated in or around thermal hotspot regions of the IC structure. For example, the implementation of the thermal conductive TSVs may be configured such that each of the thermal hotspot regions of the IC structure is vertically aligned with a respective subset of the thermally conductive TSVs. In this manner, heat generated by the thermal hotspot region can be quickly transferred to the subset of the thermal conductive TSVs. The thermal conductive TSVs are thermally coupled to a silicon carrier or other suitable heat dissipation layer, which quickly and efficiently dissipates the heat generated by the thermal hotspot regions. As a result, the device performance, reliability, and/or the lifespan of the IC structure herein can be improved.

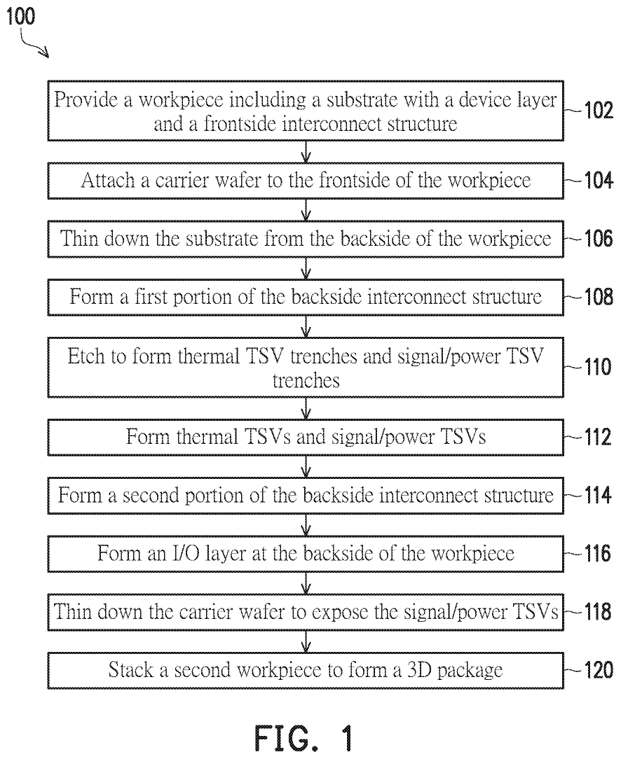

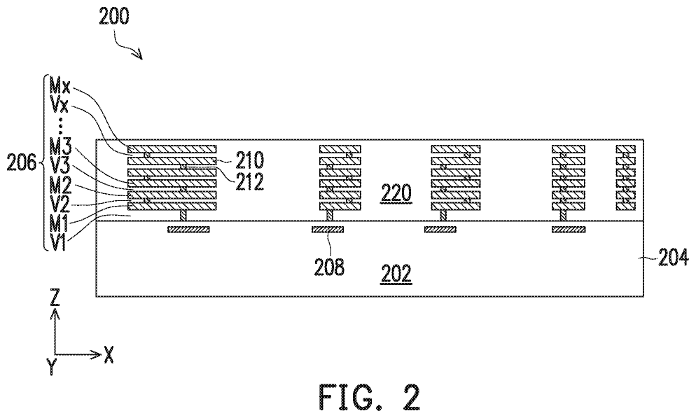

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after the method 100, and some steps described can be replaced, eliminated, or moved around for additional embodiments of the method. Not all steps are described herein in detail for reasons of simplicity. Method 100 is described below in conjunction with FIGS. 2-11, which are fragmentary cross-sectional views of a workpiece 200 and an IC structure 300 that includes the workpiece 200 at different stages of fabrication according to embodiments of the method 100 in FIG. 1. Because the workpiece 200 will be fabricated into an IC die, the workpiece 200 may be referred to herein as an IC die 200 as the context requires. For avoidance, the X, Y and Z directions in FIGS. 2-11 are perpendicular to one another. Throughout the present disclosure, like reference numerals denote like features, unless otherwise excepted.

Referring to FIGS. 1 and 2, the method 100 includes a block 102 where a workpiece 200 is provided (or received). The workpiece 200 includes a semiconductor substrate 202, a device layer 204 formed in a top portion of the substrate 202, and a frontside interconnect structure 206 formed on the device layer 204.

In some embodiments, the substrate 202 is a bulk semiconductor wafer (e.g., a silicon wafer), or a semiconductor-on-insulator wafers (e.g., silicon-on-insulator, SOI). The substrate 202 may include silicon, a compound semiconductor such as gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GalnAs), gallium indium phosphide (GalnP), gallium indium arsenide phosphide (GalnAsP), or combinations thereof.

In some embodiments, the device layer 204 is formed in a top portion of the substrate 202. The device layer 204 can include circuitry fabricated by front end-of-line (FEOL) processing. The device layer 204 may include various passive microelectronic devices and active microelectronic devices, which are generally represented by blocks 208, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide functionally distinct regions of an IC, such as a logic region (i.e., a core region), a memory region, an analog region, a peripheral region (e.g., an input/output (I/O) region), a dummy region, other suitable region, or combinations thereof. The logic region may be configured with standard cells, each of which can provide a logic device and/or a logic function, such as an inverter, an AND gate, a NAND gate, an OR gate, an NOR gate, a NOT gate, an XOR gate, an XNOR gate, other suitable logic device, or combinations thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or combinations thereof. In some embodiments, memory cells and/or logic cells include transistors and interconnect structures that combine to provide storage devices/functions and logic devices/functions, respectively.

For example, the device layer 204 can include various device components/features, such as doped wells (e.g., n-wells and/or p-wells), isolation features (e.g., shallow trench isolation (STI) structures and/or other suitable isolation structures), metal gates (e.g., a metal gate having a gate electrode and a gate dielectric), gate spacers along sidewalls of the metal gate, source/drain features (e.g., epitaxial source/drains), other suitable device components/features, or combinations thereof. In some embodiments, the device layer 204 includes planar transistors, where a channel of a planar transistor is formed in the semiconductor substrate between respective source/drains and a respective metal gate is disposed on the channel (e.g., on a portion of the semiconductor substrate in which the channel is formed). In some embodiments, the device layer 204 includes non-planar transistors, where a channel is formed in a semiconductor fin that extends from the semiconductor substrate and between respective source/drains on/in the semiconductor fin with a respective metal gate disposed on and wraps the channel of the semiconductor fin (i.e., the non-planar transistor is a fin-like field effect transistor (FinFET)). In some embodiments, the device layer 204 includes non-planar transistors, where a channel is formed in semiconductor layers suspended over the semiconductor substrate and extending between respective source/drains with a respective metal gate is disposed on and surrounds the channels (i.e., the non-planar transistor is a gate-all-around (GAA) transistor). The various transistors of the device layer 204 can be configured as planar transistors and/or non-planar transistors depending on design requirements.

The frontside interconnect structure 206 is disposed over the device layer 204. The frontside interconnect structure 206 includes one or more interconnect layers. In the depicted embodiment, the frontside interconnect structure 206 includes a via one interconnect layer (V1 level), a metal one interconnect layer (M1 level), a via two interconnect layer (V2 level), a metal two interconnect layer (M2 level), a via three interconnect layer (V3 level), a metal three interconnect layer (M3 level), and all the way to a via x interconnect layer (Vx level), and a metal x interconnect layer (Mx level), in which x represents an integer (e.g., from 2 to 10).

Each of the V1 level, M1 level, V2 Level, M2 level, V3 level, M3 level, . . . . Vx level, and Mx level may be referred to as a metal level. Vias formed at the V1 level may be referred to as V1 vias, and metal lines formed at the M1 level may be referred to as M1 metal lines. Similarly, via or metal lines formed at the V2 level, M2 level, V3 level, M3 level, . . . . Vx level, and Mx level may be referred to as V2 vias, M2 metal lines, V3 vias, M3 metal lines, . . . . Vx vias, Mx metal lines, respectively. Each level of the frontside interconnect structure 206 includes conductive features (e.g., metal lines 210, metal vias 212, and/or metal contacts) disposed in one or more dielectric layers (e.g., an interlayer dielectric (ILD) layer and an etch stop layer (ESL)). The dielectric layers of the frontside interconnect structure 206 are collectively referred to as a dielectric structure 220. In some embodiments, conductive features at a same level of the frontside interconnect structure 206, such as M1 level, are formed simultaneously. In some embodiments, conductive features at a same level of the frontside interconnect structure 206 have top surfaces that are substantially planar with one another and/or bottom surfaces that are substantially planar with one another.

In some embodiments, the V1 level includes gate contacts disposed on gate structures and contact vias disposed on source/drain contacts of the transistors formed in the device layer 204. The gate contacts connect the respective gate structures to M1 metal lines, and the contact vias connect the respective source/drain contacts to M1 metal lines. V2 level includes V2 vias disposed in the dielectric structure 220, where V2 vias connect M1 metal lines to M2 metal lines. M2 level includes M2 metal lines disposed in the dielectric structure 220. V3 level includes V3 vias disposed in the dielectric structure 220, where V3 vias connect M2 metal lines to M3 metal lines. Similarly, Vx level includes Vx vias disposed in the dielectric structure 220, where Vx vias connect Mx-1 metal lines to Mx metal lines.

In some embodiments, the metal lines 210 and the vias 212 in the same interconnect layer of the frontside interconnect structure 206 are formed by a dual damascene process, which can involve depositing conductive material for via/metal line pairs at the same time. In such embodiments, the vias 212 and metal lines 210 in the same interconnect layer may share a barrier layer and a conductive plug, instead of each having a respective and distinct barrier layer and conductive plug (e.g., where a barrier layer of a respective metal line 210 separates a conductive plug of the respective metal line 210 from a conductive plug of its corresponding, respective via 212). In some embodiments, the dual damascene process includes performing a patterning process to form interconnect openings that extend through the dielectric structure 220 to expose underlying conductive features. The patterning process can include a first lithography step and a first etch step to form trench openings of the interconnect openings (which correspond with and define metal lines 210) in the dielectric structure 220 and a second lithography step and a second etch step to form via openings of the interconnect openings (which correspond with and define vias 212) in the dielectric structure 220. The first lithography/first etch step and the second lithography/second etch step can be performed in any order (e.g., trench first via last or via first trench last). The first etch step and the second etch step are each configured to selectively remove dielectric structure 220 with respect to a patterned mask layer. The first etch step and the second etch step may be a dry etching process, a wet etching process, other suitable etching process, or combinations thereof.

After performing the patterning process, the dual damascene process can include performing a first deposition process to form a barrier material over dielectric structure 220 that partially fills the interconnect openings and performing a second deposition process to form a bulk conductive material over the barrier material, where the bulk conductive material fills remainders of the interconnect openings. In such embodiments, the barrier material and the bulk conductive material are disposed in the interconnect openings and over a top surface of the dielectric structure 220. A planarization process, such as a chemical mechanical planarization (CMP) process, is then performed to remove excess bulk conductive material and barrier material from over the top surface of the dielectric structure 220, resulting in the patterned via layer (e.g., vias 212) and the patterned metal layer (e.g., metal lines 210) of one of the interconnect layers of the frontside interconnect structure 206. The CMP process planarizes top surfaces of the dielectric structure 220 and the vias 212 and/or the metal lines 210. The barrier material and the bulk conductive material may fill the trench openings and the via openings of the interconnect openings without interruption, such that barrier layers and conductive plugs of the metal lines 210 and the vias 212 may each extend continuously from the metal lines 210 to respective vias 212 without interruption.

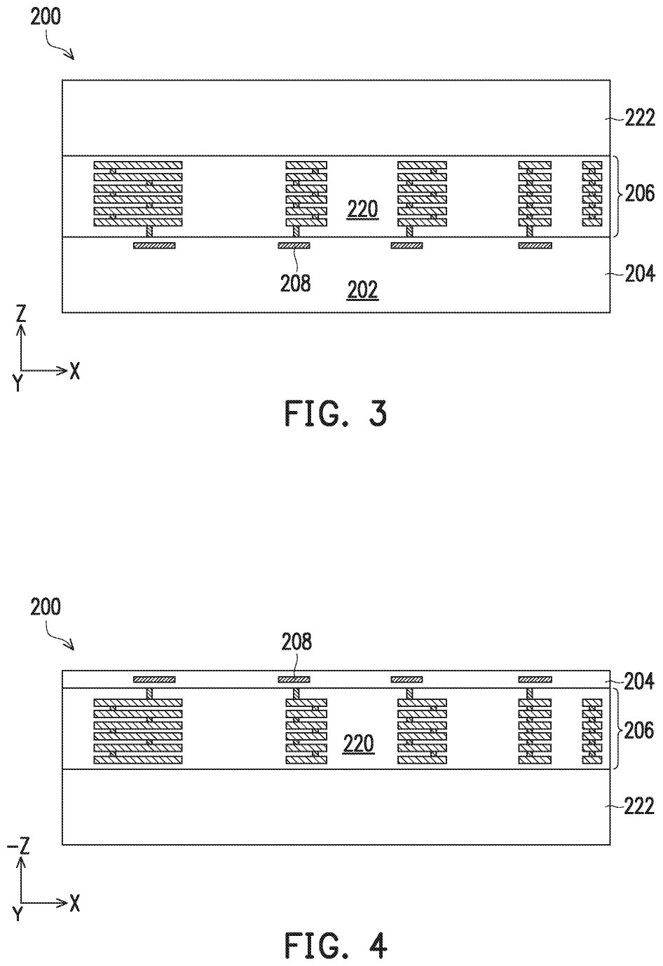

Referring to FIGS. 1 and 3, the method 100 includes a block 104 where the frontside of the workpiece 200 is attached to a carrier substrate 222, which allows the workpiece 200 to be flipped upside down. This makes the workpiece 200 accessible from the backside of the workpiece 200 for further processing. The carrier substrate 222 may be a bulk semiconductor wafer (e.g., a silicon wafer) and also referred to as the carrier wafer 222. In some embodiments, the carrier substrate 222 may, for example, be or comprise silicon, monocrystalline silicon/CMOS bulk, or another suitable semiconductor material. The carrier substrate 222 may be attached to the workpiece 200 with any suitable attaching processes, such as direct bonding, hybrid bonding, using adhesive, or other bonding methods. A bonding process may further include alignment, annealing, and/or other processes.

Referring to FIGS. 1 and 4, the method 100 includes a block 106 where the workpiece 200 is flipped upside down and further thinned down from the backside of the workpiece 200, such that a majority portion of the semiconductor substrate 202 is removed. The thinning process may include a mechanical grinding process and/or a chemical thinning process. A substantial amount of semiconductor substrate 202 may be first removed during a mechanical grinding process. Afterwards, a chemical thinning process may apply an etching chemical to the backside of the semiconductor substrate 202 to further thin down the semiconductor substrate 202. In the illustrated embodiment, the portion of the semiconductor substrate 202 underneath the device layer 204 is substantially removed, and a backside surface of the device layer 204 is exposed.

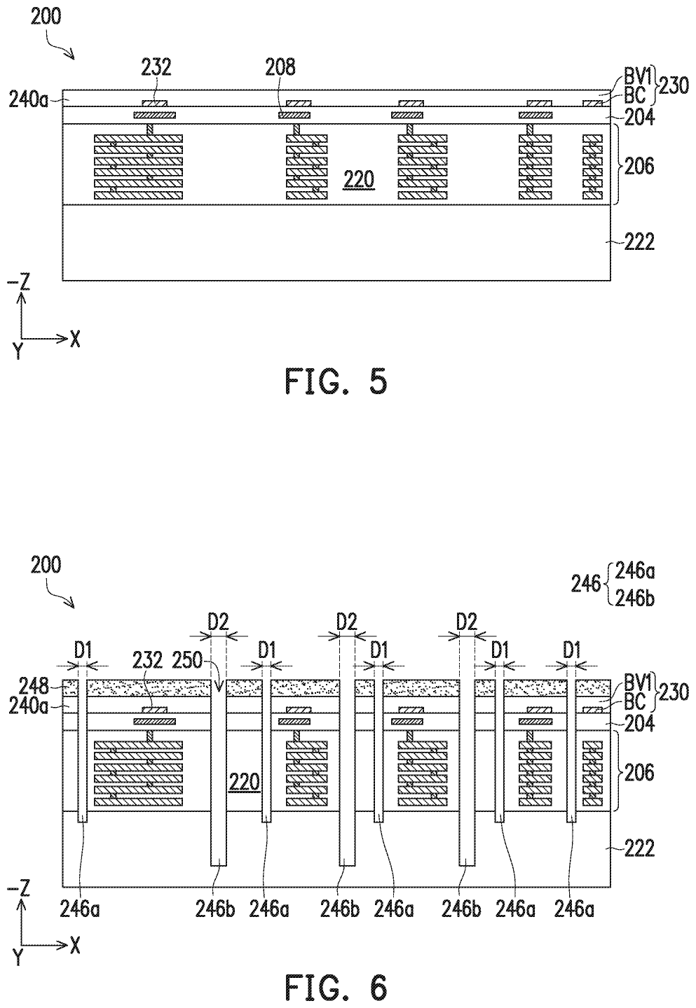

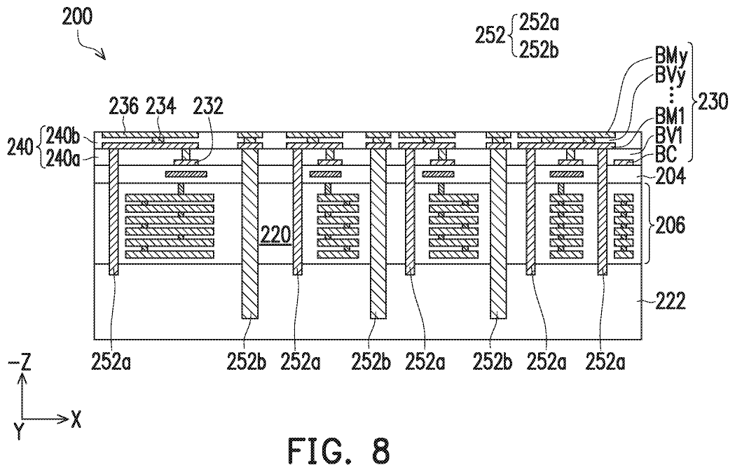

Referring to FIGS. 1 and 5, the method 100 includes a block 108 where a first portion of a backside interconnect structure 230 is formed over the backside of the workpiece 200. Similar to the frontside interconnect structure 206, the backside interconnect structure 230 includes one or more connection layers. The backside interconnect structure 230, upon completion (such as depicted in FIG. 8) may include a backside contact layer (BC level), a backside via one interconnect layer (BV1 level), a backside metal one interconnect layer (BM1 level), a backside via two interconnect layer (BV2 level), a backside metal two interconnect layer (BM2 level), and all the way to a backside via y interconnect layer (BVy level), and a backside metal y interconnect layer (My level), in which y represents an integer (e.g., from 2 to 10). Each level of the backside interconnect structure 230 includes conductive features (e.g., backside metal contacts 232, backside metal vias 234, or backside metal lines 236) disposed in one or more dielectric layers (e.g., an interlayer dielectric (ILD) layer and an etch stop layer (ESL)). The dielectric layers of the backside interconnect structure 230 are collectively referred to as a backside dielectric structure 240. In some embodiments, conductive features at a same level of the backside interconnect structure 230, such as BM1 level, are formed simultaneously. In some embodiments, conductive features at a same level of the backside interconnect structure 230 have top surfaces that are substantially planar with one another and/or bottom surfaces that are substantially planar with one another. The formation of the backside dielectric structure 240, backside metal contacts 232, backside metal vias 234, and backside metal lines 236 are similar to the formation of the dielectric structure 220 and the metal features therein described above with reference to the frontside interconnect structure 206, which is omitted herein for the sake of simplicity.

In some embodiments, the BC level includes backside metal contacts 232 physically and/or electrically connected to backside surfaces of the source/drain contacts of the transistors formed in the device layer 204. BM1 level includes BM1 metal lines disposed in the dielectric structure 220. BV1 level includes BV1 vias disposed in the backside dielectric structure 240, where BV1 vias connect backside contacts to BM1 metal lines. Similarly, BMy level includes BMy metal lines disposed in the dielectric structure 220, and BVy level includes BVy vias disposed in the backside dielectric structure 240, where BVy vias connect BMy-1 metal lines to BMy metal lines.

Still referring to FIG. 5, the first portion of the backside interconnect structure 230 formed over the backside of the workpiece 200 at the block 108 includes first a few backside interconnect layers of the backside interconnect structure 230. In the depicted embodiment, the first portion of the backside interconnect structure 230 includes the backside metal contacts 232 in the BC level and a first portion of the backside dielectric structure 240 corresponding to the dielectric layers in the BC level and the BV1 level. The first portion of the backside dielectric structure 240 formed at the block 108 is denoted as the backside dielectric structure 240a. The backside dielectric structure 240a covers the backside metal contacts 232. In various non-limiting examples, the first portion of the backside interconnect structure 230 formed over the backside of the workpiece 200 at the block 108 may include extra interconnect layers beyond the BV1 level, such as BV2 level or above, yet under the BMy level.

Referring to FIGS. 1 and 6, the method 100 includes a block 110 wherein a plurality of TSV trenches 246 are formed by etching from the backside of the workpiece 200. The TSV trenches 246 extend through the backside dielectric structure 240a, the device layer 204, and the dielectric structure 220, and partially into the carrier substrate 222. In some embodiments, forming the TSV trenches 246 includes forming a patterned mask layer 248 having openings 250 therein that exposes the backside surface of the backside dielectric structure 240a, and etching the backside dielectric structure 240a and subsequently the device layer 204 and the dielectric structure 220 using the patterned mask layer 248 as an etch mask. The patterned mask layer 248 may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer 248 is a patterned hard mask layer (e.g., a silicon nitride layer). In some embodiments, the patterned mask layer 248 is a patterned resist layer. The etching may be a dry etching process, a wet etching process, other etching process, or combinations thereof. In some embodiments, the etching process is an isotropic dry etch. In some embodiments, a Bosch process, is implemented to extend the TSV trenches 246 through the backside dielectric structure 240a, the device layer 204, the dielectric structure 220, and partially into the carrier wafer 222. A Bosch process generally refers to a high-aspect ratio plasma etching process that involves alternating etch phases and deposition phases, where a cycle includes an etch phase and a deposition phase and the cycle is repeated until the trenches 246 has a desired depth.

Still referring to FIG. 6, in the depicted embodiment, the openings 250 include two different dimensions, namely the narrower ones having a width D1 and the wider ones having a width D2 (i.e., D1<D2). During the etching process in forming the TSV trenches 246, the vertical etching rate corresponding to the wider openings is generally larger than the vertical etching rate corresponding to the narrower openings, since more etchants may enter the trenches through the wider openings and etch the underneath layers more efficiently. The opening widths D1 and D2 may be transferred to the TSV trenches 246 during the etching process, respectively. The TSV trenches 246 corresponding to the narrower openings are denoted as the TSV trenches 246a, and the TSV trenches 246 corresponding to the wider openings are denoted as the TSV trenches 246b. The TSV trenches 246a has a less height than the TSV trenches 246b due to the less vertical etching rate. The difference between the widths D1 and D2 and the etching time (or etching cycles) are controlled in a way such that both the TSV trenches 246a and 246b extend partially into the carrier substrate 222 with the TSV trenches 246a being less extending into the carrier substrate 222. In some embodiments, the widths D1 and D2 range from about 0.1 μm to about 50 μm, the heights of the TSV trenches 246a and 246b range from about 0.1 μm to about 500 μm, and a ratio of the height and respective widths of the TSV trenches 246a and 246b ranges from about 1 to about 10. In some embodiments, a ratio between D2 and D1 (D2/D1) ranges from about 1.1 to about 3. This ratio is not arbitrary. If D2/D1 is less than about 1.1, the height difference between the TSV trenches 246a and 246b may be trivial and cause difficulty in later process steps of thinning the carrier substrate 222 to expose the TSVs formed in the TSV trenches 246b. If D2/D1 is larger than about 3, the height difference between the TSV trenches 246a and 246b may be too large, such that when the TSV trenches 246a extend into the carrier substrate 222, the TSV trenches 246 may have extend through the carrier substrate 222.

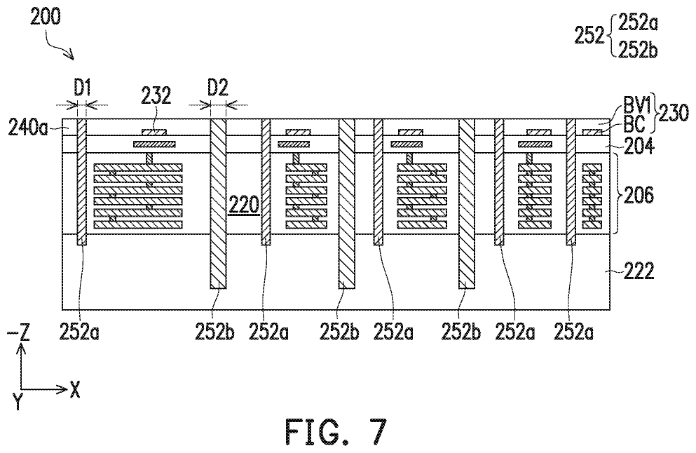

Referring to FIGS. 1 and 7, the method 100 includes a block 112 where TSVs 252 are formed in the TSV trenches 246. In some embodiments, forming the TSVs 252 includes filling the TSV trenches 246 with conductive material(s) such as tungsten, ruthenium, titanium, titanium nitride, tantalum nitride, copper, aluminum, other conductive material(s), or any combination thereof, and performing a planarization process (e.g., a CMP process) to remove excess bulk conductive material from over the workpiece 200. The patterned mask layer 248 may also be removed in the planarization process. After the planarization process, the ends of the TSVs 252 are in the same plane (e.g., the plane comprising the exposed surface of the backside dielectric structure 240a), while the opposing ends of the TSVs 252 as extending into the carrier substrate 222 are located at two different depths. Particularly, the TSVs 252 formed in the shorter TSV trenches 246a function as thermal conductive TSVs for dissipating heat into the carrier substrate 222. These shorter TSVs 252 are denoted as thermal conductive TSVs 252a. Other TSVs 252 formed in the longer TSV trenches 246b function as power and/or signal TSVs for delivering power and/or signal to the device layer 204 or through the workpiece 200. These longer TSVs 252 are denoted as power/signal TSVs 252b. The thermal conductive TSVs 252a may be electrically isolated from the power/signal TSVs 252b. The conductive material(s) in the thermal conductive TSVs 252a and the power/signal TSVs 252b may be the same or different. For example, the thermal conductive TSVs 252a and the power/signal TSVs 252b may both be formed of the same conductive material, such as copper. Alternatively, the thermal conductive TSVs 252a may be formed of a conductive material having a higher thermal conductivity than the power/signal TSVs 252b. For example, the power/signal TSVs 252b may be formed of aluminum, and the thermal conductive TSVs 252a may be formed of copper.

Referring to FIGS. 1 and 8, the method 100 includes a block 114 where a second portion of the backside interconnect structure 230 is formed over the backside of the workpiece 200 with metal layers disposed in a dielectric structure 240b added to the backside dielectric structure 240a. The newly added dielectric structure 240b of the second portion of the backside interconnect structure 230 can be considered as an extension of the backside dielectric structure 240a in the vertical direction. The backside dielectric structures 240a and 240b collectively define the backside dielectric structure 240. The BV1 vias, BM1 metal lines, and up to the B Vy vias, and BMy metal lines are formed in the backside dielectric structure 240, such that first and second portions of the backside interconnect structure 230 are physically and electrically connected. In the depicted embodiment, the thermal conductive TSVs 252a and the power/signal TSVs 252b are physically connected to the respective BM1 metal lines. The present disclosure contemplates the thermal conductive TSVs 252a and the power/signal TSVs 252b are physically connected to metal lines in a backside interconnect layer other than the BM1 layer. Further, some of the thermal conductive TSVs 252 may have thermal (and electrical) coupling with the transistors formed in the device layer 204, such as through a thermal path comprising BM1 metal line, BV1 via, backside metal contact 232, and the source/drain regions of the respective transistors. Thus, the thermal conductive TSVs 252 may dissipate heat directly from some high-power transistors. Some of the thermal conductive TSVs 252 may be electrically isolated from circuitries in the device layer 204 but dissipate heat as being positioned around the hotspot regions. Some of the power/signal TSVs 252b may have electrical coupling with the transistors formed in the device layer 204 to deliver power and/or signal to the circuitries in the device layer 204. Some of the power/signal TSVs 252b may be electrically isolated from circuitries in the device layer 204 but to deliver power and/or signal through the workpiece 200 to other IC chip(s) stacked on the workpiece 200.

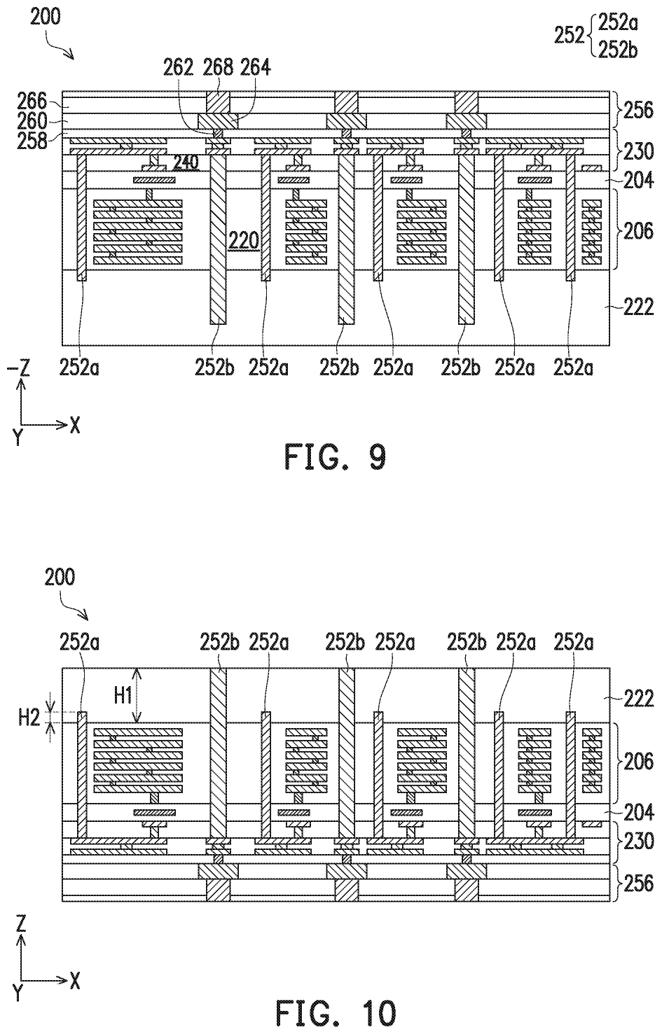

Referring to FIGS. 1 and 9, the method 100 includes a block 116 where an input/output (I/O) structure 256 is formed on the backside of the workpiece 200. The I/O structure 256 may include a dielectric layer 258 disposed on the backside dielectric structure 240 and a passivation layer 260 disposed on the dielectric layer 258. The passivation layer 260 and the dielectric layer 258 may include different dielectric materials. I/O vias 262 are formed in the dielectric layer 258, and I/O contacts 264 are formed in the passivation layer 260. In some embodiments, the I/O contacts 264 are aluminum pads or aluminum-copper pads. The I/O structure 256 may further include one or more polyimide layers 266 disposed on the passivation layer 260 and other contact features formed in the polyimide layers 266. In one example, under-bump metallization (UBM) structures 268 are formed in the polyimide layers 266 and physically and/or electrically connect to the I/O contacts 264.

Referring to FIGS. 1 and 10, the method 100 includes a block 118 where the workpiece 200 is flipped back and further thinned down from the frontside of the workpiece 200, such that a portion of the carrier substrate 222 is removed and the power/signal TSVs 252b are revealed. As a comparison, the thermal conductive TSVs 252a are still embedded in the remaining portions of the carrier substrate 222. The thinning process may include a mechanical grinding process and/or a chemical thinning process. The remaining portion of the carrier substrate 222 has a thickness H1. The thermal conductive TSVs 252a embed in the carrier substrate 222 for a distance H2. A ratio between H2 and H1 (H2/H1) range from about 20% to about 80% in some embodiments. This ratio is not arbitrary. If H2/H1 is less than about 20%, there may not be sufficient contact between the thermal conductive TSVs 252a and the semiconductor material (e.g., Si) of the carrier substrate 222, such that heat may not be effectively dissipated into the semiconductor material and further spread out. If H2/H1 is larger than about 80%, the thermal conductive TSVs 252a may be accidentally exposed during the thinning process due to less margin for manufacturing tolerance.

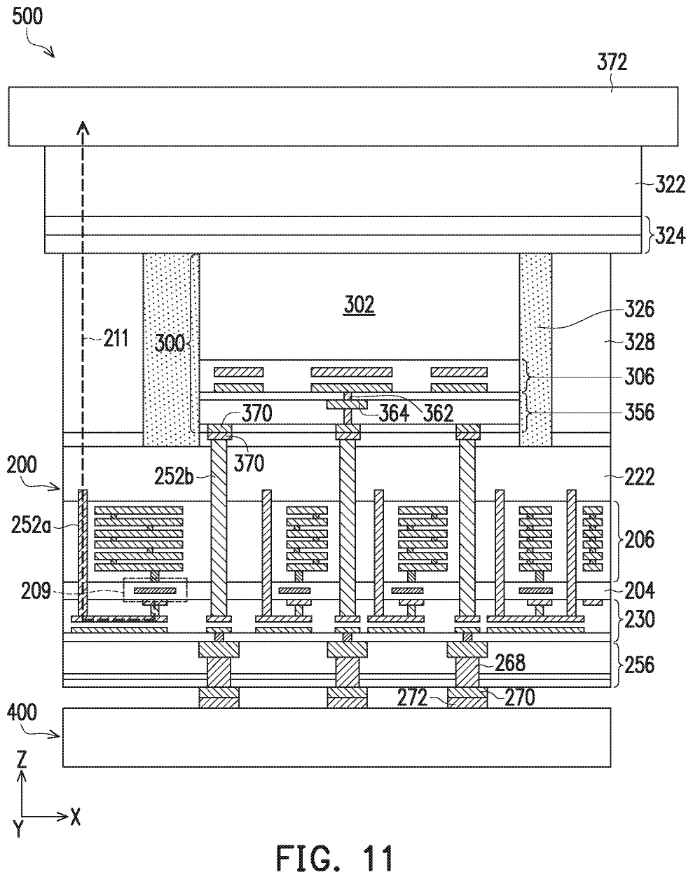

Referring to FIGS. 1 and 11, the method includes a block 120 where the workpiece 200 (e.g., IC die 200) is stacked with another workpiece 300 (e.g., IC die 300) and a package substrate 400 to form an IC structure 500. In some embodiments, the IC structure 500 is a portion of three-dimensional integrated circuit (3DIC) package, such as a chip-on-wafer-on-substrate (CoWoS) package, an integrated-fan-out (InFO) package, a system on integrated chip (SoIC) package, other 3DIC package, or a hybrid package that implements a combination of multichip packaging technologies. The package substrate 400 may be an interposer, a redistribution layer (RDL), a printed circuit board (PCB), a printed wiring board, other packaging structure and/or substrate, or combinations thereof. In some embodiments, the IC die 200 is flip-chip bonded to the package substrate 400 through solder bumps (or solder balls) 270 sandwiched between the under-bump metallization (UBM) structures 268 of the IC die 200 and the soldering pads 272 of the package substrate 400.

The IC die 300 is attached to its carrier substrate 322 through an adhesive layer 324. The IC die 300 is further laterally stacked between oxide compound 326 and dummy silicon blocks (or pillars) 328. The IC die 300 includes a substrate 302 with circuitries formed in a device layer located at the top portion of the substrate 302. A frontside interconnect structure 306 is formed on the substrate 302. An I/O layer 356 is formed on the frontside interconnect structure 306. The I/O layer 356 includes I/O vias 362 and I/O contacts 364. The IC die 300 is flipped upside-down and bonded to the IC die 200 with any suitable attaching processes, such as direct bonding, hybrid bonding, using adhesive, or other bonding methods. A bonding process may further include alignment, annealing, and/or other processes. In the depicted embodiment, the IC die 200 and IC die 300 are bonded through a hybrid bonding process, in which bonding pads 370 from the IC die 200 and IC die 300 are bonded to each other and the dielectric layers surrounding the bonding pads 370 are also bonded to each other. The power/signal TSVs 252b extend through the IC die 200 and provide power and/or signal from the package substrate 400 to the IC die 300. The carrier substrate 322 is further attached to a cooling medium 372. The cooling medium 372 may be a passive heat dissipating layer (e.g., a heat sink) or an active heat dissipating apparatus (e.g., a cooling fan).

Still referring to FIG. 11, the thermal conductive TSVs 252a dissipate heat from the device layer 204 to the cooling medium 372. For example, the dashed box 209 in the device layer 204 represents a thermal hotspot region. The thermal conductive TSVs 252a provide a heat dissipating path represented by a dashed line 211, such that heat generated from the thermal hotspot region 209 may prorogate through the backside contact, backside via, and backside metal lines in the backside interconnect structure 230 to the thermal conductive TSVs 252a. The thermal conductive TSVs 252a further transmit the heat into the silicon material of the carrier substrate 222. The heat propagates into the carrier substrate 222, subsequently travels through the dummy silicon blocks 328 and into the carrier substrate 322, and is eventually dissipated by the cooling medium 372 to ambient environment.

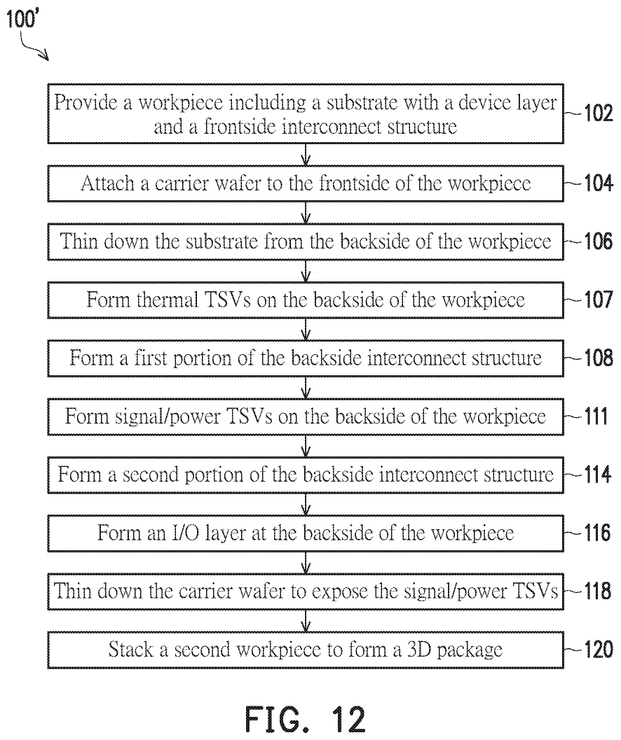

Reference is now made to FIG. 12, which is a flowchart illustrating a method 100′ of forming a semiconductor device from a workpiece according to some alternative embodiments of the present disclosure. Some aspects of the method 100′ are the same as the method 100, and will be briefly discussed below. Other aspects of the method 100′ are different from the method 100, and will be described in more details.

The aspects of the operations at blocks 102, 104, and 106 of the method 100′ are substantially the same as those of the operations at blocks 102, 104, and 106 of the method 100 as discussed above with reference to FIGS. 2, 3, and 4.

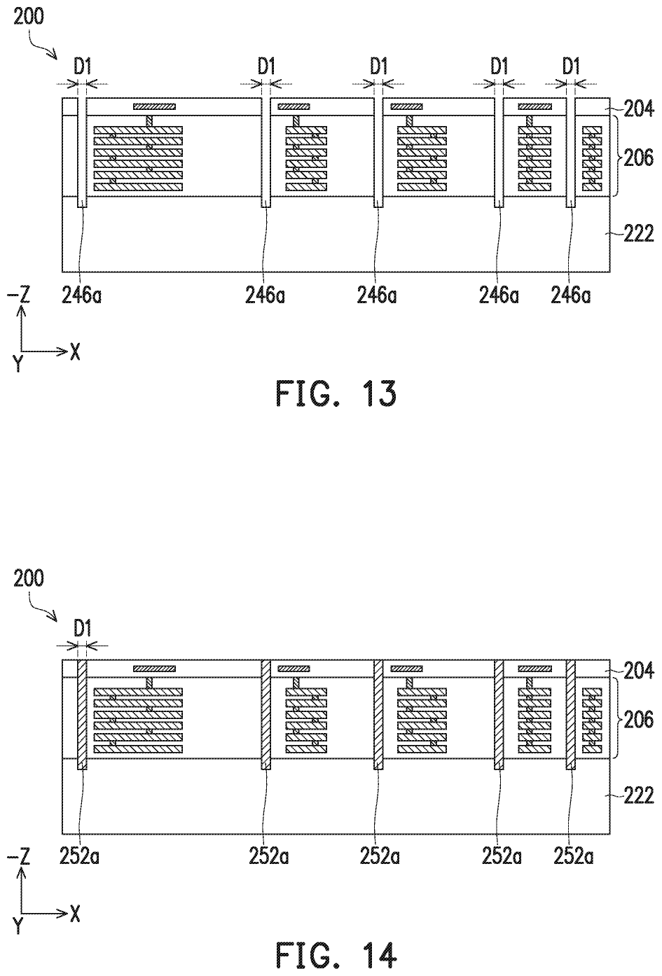

Referring to FIG. 12 and FIGS. 13-14, the method 100′ includes a block 107 where the TSV trenches 246a and the thermal conductive TSVs 252a are formed prior to the forming of the TSV trenches 246b and the respective power/signal TSVs 252b. In the depicted embodiment as shown in FIG. 13, the TSV trenches 246a are also formed prior to the formation of the first portion of the backside interconnect structure 230. In some embodiments, forming the TSV trenches 246a includes forming a first patterned mask layer (not shown) having openings with the width D1, and etching the device layer 204, the dielectric structure 220, and partially the carrier substrate 222 using the first patterned mask layer as an etch mask. Without a need to form the TSV trenches 246b simultaneously as in the method 100, the depth of the TSV trenches 246a can be individually controlled in a time mode in the method 100′. Subsequently, the thermal conductive TSVs 252a are formed in the TSV trenches 246a, such as shown in FIG. 14.

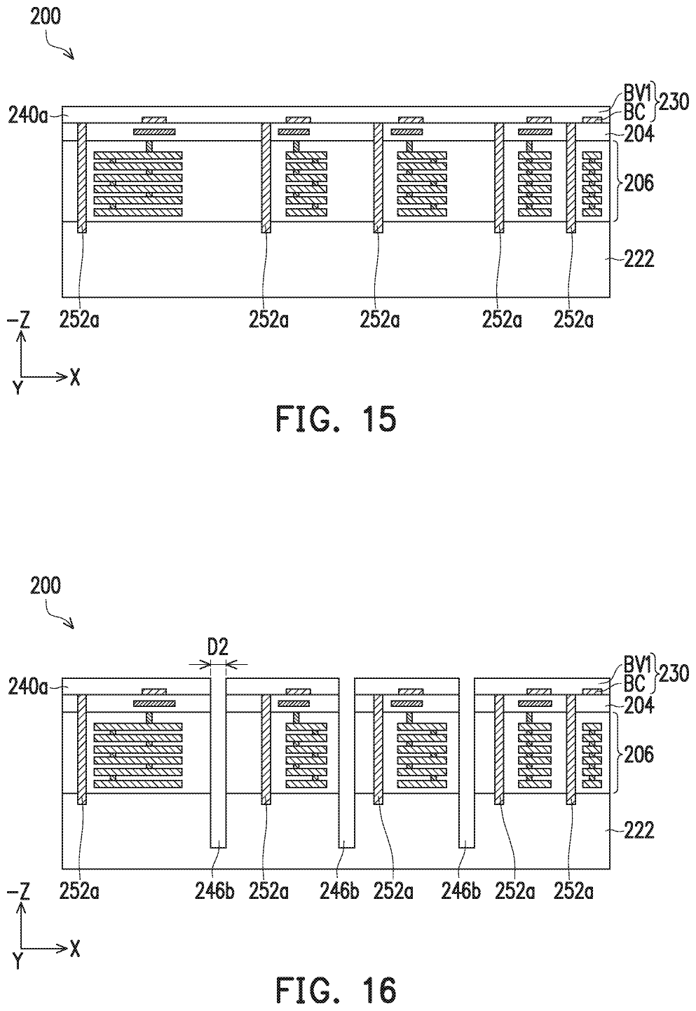

The aspects of the operations at block 108 of the method 100′ are substantially the same as those of the operations at block 108 of the method 100 as discussed above where a first portion of a backside interconnect structure 230 is formed over the backside of the workpiece 200, such as shown in FIG. 15.

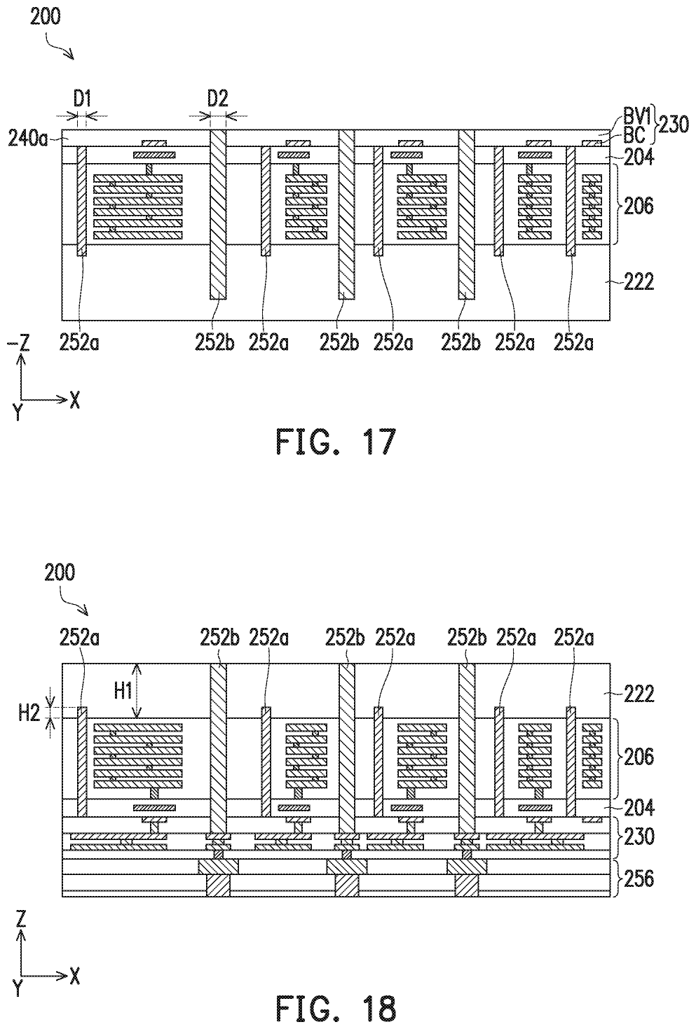

Referring to FIG. 12 and FIGS. 16-17, the method 100′ includes a block 111 where the TSV trenches 246b and the power/signal TSVs 252b are formed. In the depicted embodiment as shown in FIG. 16, forming the TSV trenches 246b includes forming a second patterned mask layer (not shown) having openings with the width D2, and etching the first portion of the backside interconnect structure 230, the device layer 204, the dielectric structure 220, and partially the carrier substrate 222 using the second patterned mask layer as an etch mask. Without a need to form the TSV trenches 246a simultaneously as in the method 100, the depth of the TSV trenches 246b can be individually controlled in a time mode in the method 100′. Also, since the TSV trenches 246a and 246b are formed separately, the width D2 of the TSV trenches 246b can be independent from the width D1 of the TSV trenches 246a. For example, the width D1 may be less than, equal to, or larger than the width D2. Subsequently, the power/signal TSVs 252b are formed in the TSV trenches 246b, such as shown in FIG. 17. Notably, the end portions of the thermal conductive TSVs 252a and the power/signal TSVs 252b are not in the same plane. The end portions of the thermal conductive TSVs 252a are closer to the device layer 204, such as coplanar with the bottom surface of the device layer 204 as depicted in FIG. 17.

The aspects of the operations at blocks 114, 116, and 118 of the method 100′ are substantially the same as those of the operations at blocks 114, 116, and 118 of the method 100 as discussed above. The resultant structure at the conclusion of the operation at block 118 is shown in FIG. 18, in which the end portions of the power/signal TSVs 252b are exposed.

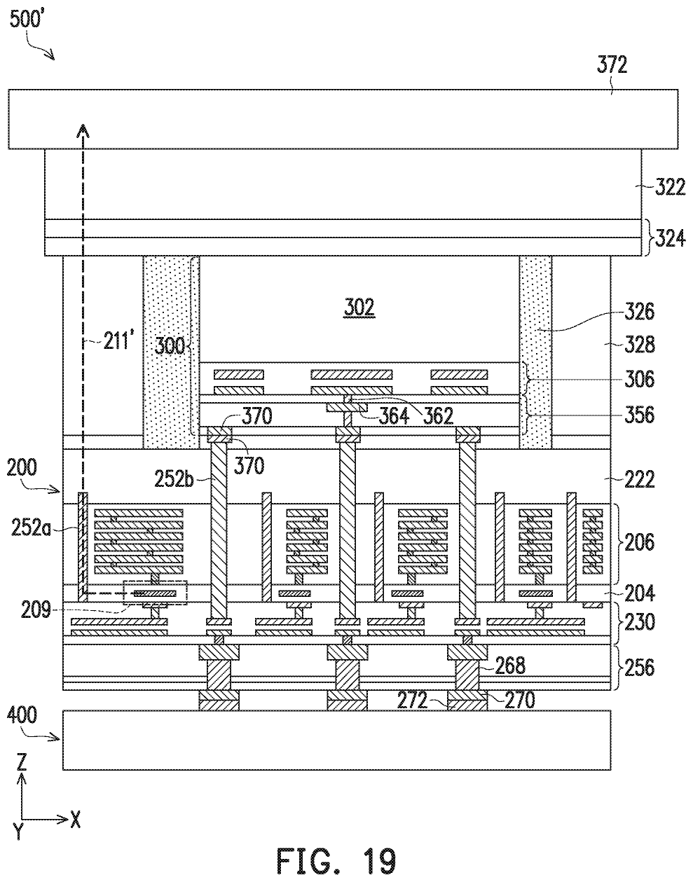

The aspects of the operations at block 120 of the method 100′ are substantially the same as those of the operations at block 120 of the method 100 as discussed above where the workpiece 200 is stacked with another workpiece 300 and a package substrate 400 to form the IC structure 500, such as shown in FIG. 19.

Thermal conductive TSVs 252a dissipate heat from the device layer 204 to the cooling medium 372. For example, the dashed box 209 in the device layer 204 represents a thermal hotspot region. The thermal conductive TSVs 252a provide a heat dissipating path represented by a dashed line 211′, such that heat generated from the thermal hotspot region 209 may prorogate to the thermal conductive TSVs 252a (without through the backside interconnect structure 230) and further into the silicon material of the carrier substrate 222. The heat subsequently travels through the dummy silicon blocks 328 and into the carrier substrate 322, and is eventually dissipated by the cooling medium 372 to ambient environment.

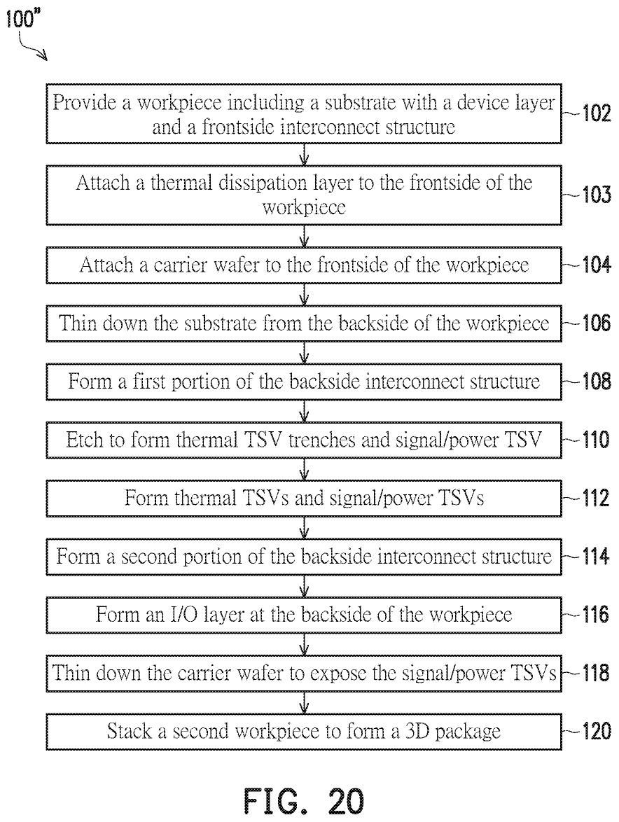

Reference is now made to FIG. 20, which is a flowchart illustrating a method 100″ of forming a semiconductor device from a workpiece according to some alternative embodiments of the present disclosure. Some aspects of the method 100″ are the same as the method 100, and will be briefly discussed below. Other aspects of the method 100″ are different from the method 100, and will be described in more details.

The aspects of the operations at block 102 of the method 100″ are substantially the same as those of the operations at block 102 of the method 100 as discussed above with reference to FIG. 2.

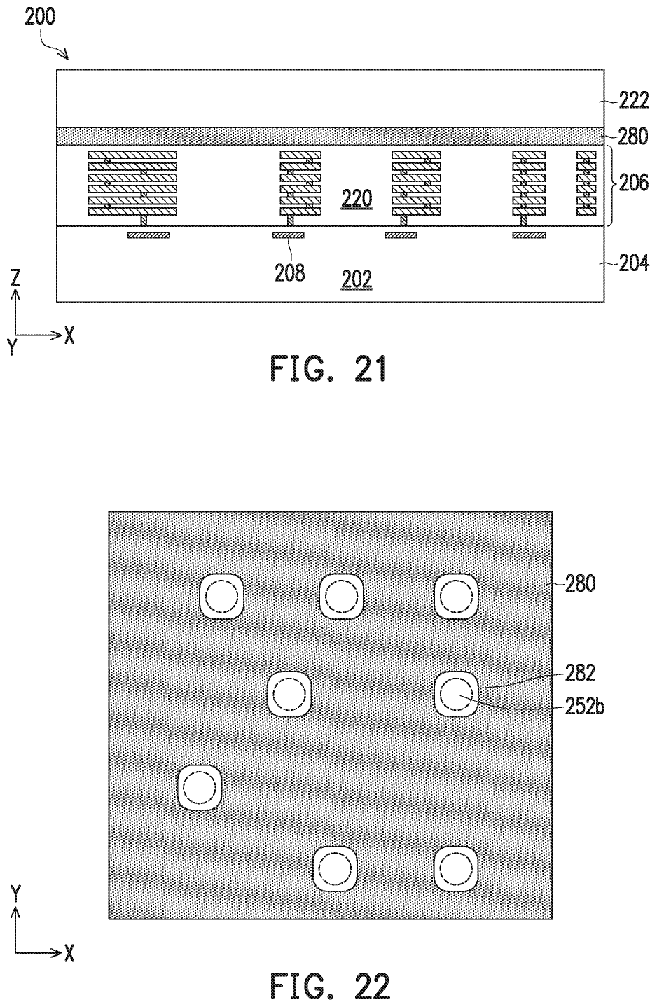

Referring to FIGS. 20 and 21, the method 100″ includes a block 103 where a heat dissipation layer 280 is formed on the frontside interconnect structure 206 and a block 104 where the carrier substrate 222 is attached to the heat dissipation layer 280. The resultant structure at the conclusion of the operations at block 104 is shown in FIG. 21.

In some embodiments, the heat dissipation layer 280 includes materials with a thermal conductivity greater than about 1 W m⁻¹ K⁻¹. By way of example and not limitation, the heat dissipation layer 280 may include cobalt, titanium, tungsten, copper, aluminum, tantalum, titanium nitride, tantalum nitride, gold, silver, another metal, a metal alloy, or combinations thereof. In some embodiments, the heat dissipation layer 280 have a thickness that ranges from about 10 nm to about 1 μm. Thicker heat dissipation layers (e.g., thicker than about 1 μm) are possible. However, thicker heat dissipation layers may require thicker passivation layers, which increase the fabrication cost and the overall height of an IC structure. Accordingly, thinner heat dissipation layers (e.g., thinner than about 10 nm) are also possible. However, thinner heat dissipation layers exhibit a limited heat transfer capacity, which can pose limitations to the heat dissipation process. For example, a thin heat dissipation layer may be unable to transfer heat at a satisfactory rate.

The heat dissipation layer 280 can include openings 282 to allow conductive structures between adjacent chips and/or within the chip to traverse through without coming in physical contact with the heat dissipation layer 280. In some embodiments, this means that the heat dissipation layer 280 can conform to the chip's layout so that the heat dissipation layer does not obstruct electrically conductive structures extending from one chip to another or within the chip. For example, such as shown in a top view of the heat dissipation layer 280 in FIG. 22, the heat dissipation layer 280 can include openings 282 that allow power/signal TSVs 252b (represented by dashed circles in FIG. 22) to travel through. Openings 282 in the heat dissipation layer can be formed with a combination of photolithography and etching operations. During the photolithography and etching operations, portions of the heat dissipation layer are etched to form the openings 282. A planarization process (e.g., a CMP process) polishes the workpiece 200 so that the top surface of the heat dissipation layer 280 is substantially flat to attach to the carrier substrate 222, such as shown in FIG. 21.

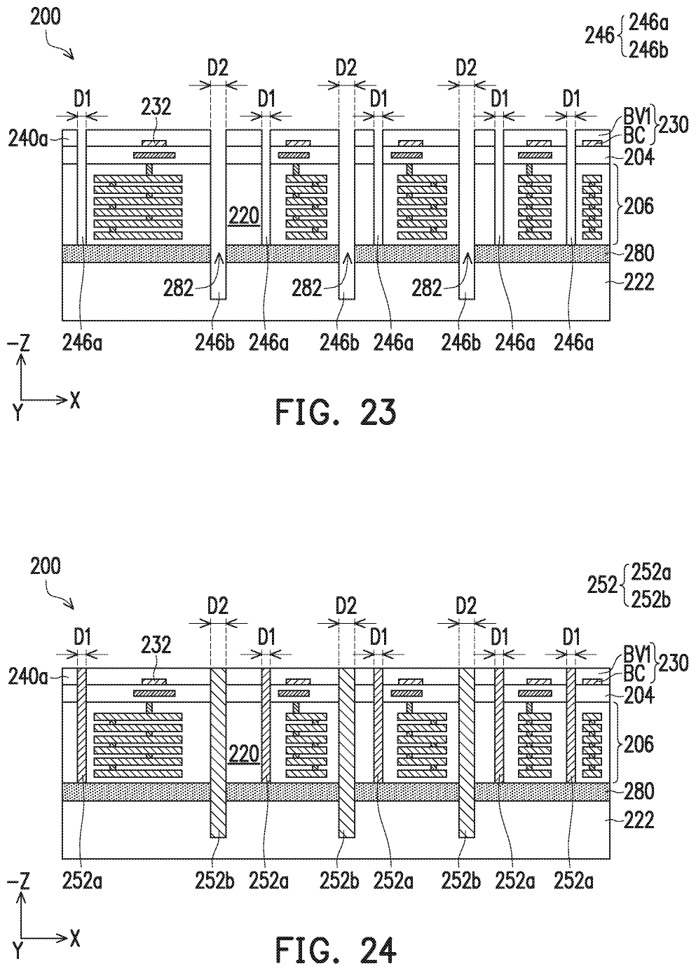

The aspects of the operations at blocks 104, 106, 108, and 110 of the method 100′ are substantially the same as those of the operations at blocks 104, 106, 108, and 110 of the method 100 as discussed above. The resultant structure at the conclusion of the operation at block 110 is shown in FIG. 23, in which the TSV trenches 246a and 246b are formed. The heat dissipation layer 280 may further function as an etching stop layer during the etching process at block 110, such that the TSV trenches 246a for thermal conductive TSVs 252a will stop at the heat dissipation layer 280, while the TSV trenches 246b will extend through the openings 282 of the heat dissipation layer 280 and extends partially into the carrier substrate 222. Since the depth of the TSV trenches 246a is automatically controlled by the heat dissipation layer 280 as an etching stop layer, the width D2 of the TSV trenches 246b can be independent from the width D1 of the TSV trenches 246a. For example, the width D1 may be less than, equal to, or larger than the width D2.

The aspects of the operations at block 112 of the method 100″ are substantially the same as those of the operations at block 112 of the method 100, in which thermal conductive TSVs 252a and power/signal TSVs 252b are formed in the TSV trenches 246a and 246b, respectively, such as shown in FIG. 24.

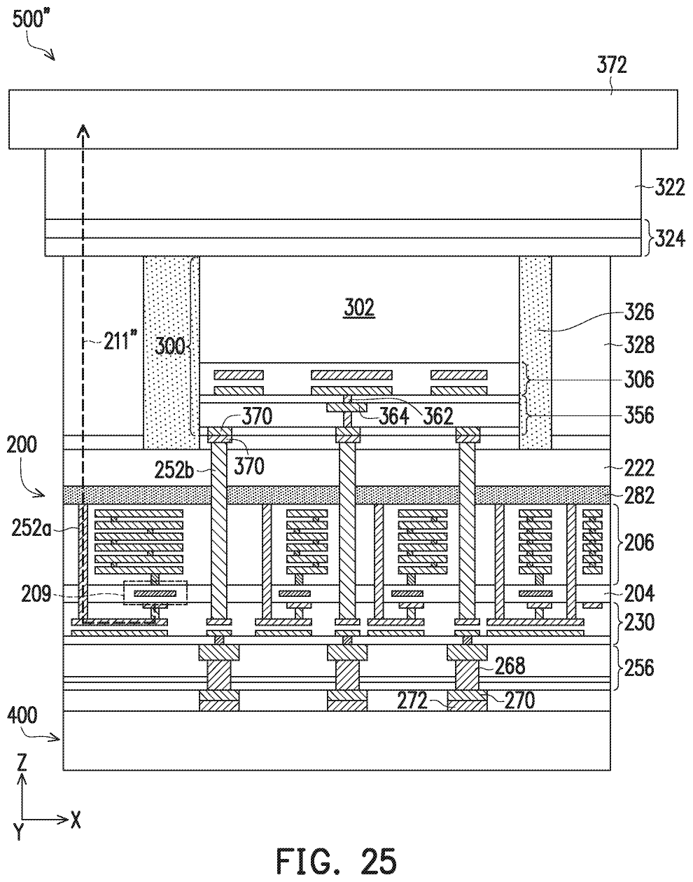

The aspects of the operations at blocks 114, 116, 118, and 120 of the method 100″ are substantially the same as those of the operations at blocks 114, 116, 118, and 120 of the method 100. The resultant structure at the conclusion of the operations at block 120 is shown in FIG. 25.

Thermal conductive TSVs 252a dissipate heat from the device layer 204 to the cooling medium 372 though the heat dissipation layer 280. For example, the dashed box 209 in the device layer 204 represents a thermal hotspot region. The thermal conductive TSVs 252a provide a heat dissipating path represented by a dashed line 211″, such that heat generated from the thermal hotspot region 209 may prorogate to the thermal conductive TSVs 252a through the backside interconnect structure 230 and further into the heat dissipation layer 280 and spread into the silicon material of the carrier substrate 222. The heat subsequently travels through the dummy silicon blocks 328 and into the carrier substrate 322, and is eventually dissipated by the cooling medium 372 to ambient environment.

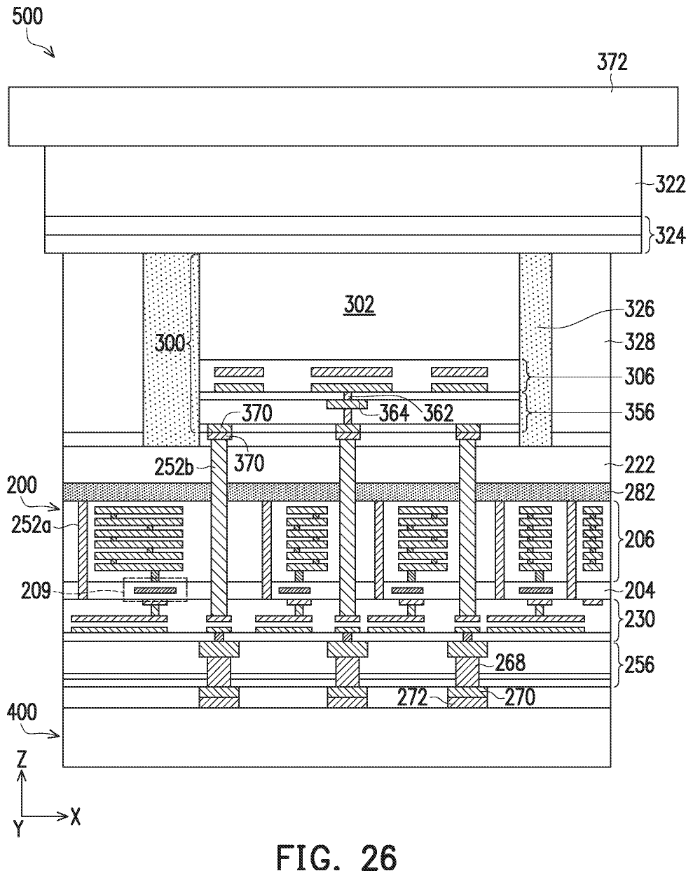

The method 100″ may also adopts the operations at blocks 107 and 111 of the method 100′, in which thermal conductive TSVs 252a and power/signal TSVs 252b are formed separately. FIG. 26 illustrates such an embodiment at the conclusion of the operations at block 120, in which the end portions of the thermal conductive TSVs 252a and the power/signal TSVs 252b are not in the same plane. The end portions of the thermal conductive TSVs 252a are closer to the device layer 204, such as coplanar with the bottom surface of the device layer 204 as depicted in FIG. 26.

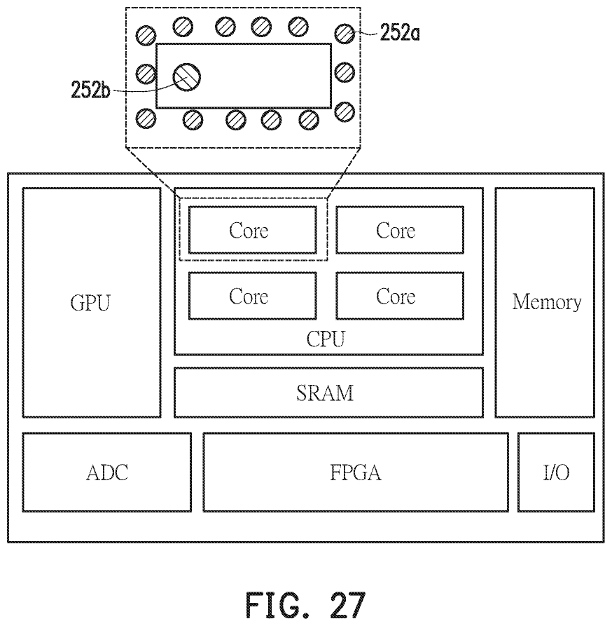

Reference is now made to FIG. 27. FIG. 27 depicts a visual representation of a System-on-Chip (SoC) package, highlighting its various integral components. The SoC package includes a graphics processing unit (GPU) and a central processing unit (CPU), each of which can be a potential source of significant heat. The CPU further includes multiple cores. Certain cores may generate more heat than others and host thermal hotspot regions within the SoC. The SoC package also includes memory component, which typically serves to provide storage for the SoC's data and operational instructions. Positioned centrally and beneath the CPU is the static random-access memory (SRAM), a type of semiconductor memory designed for high-speed, low-power applications. Depicted on the bottom left of the SoC is the analog-to-digital converter (ADC), responsible for converting analog signals into digital data for processing. Next to the ADC is the field-programmable gate array (FPGA), integrated circuits that can be custom-programmed post-manufacturing to execute a range of tasks. Completing the layout, on the bottom right, is the input/output (I/O) section, which manages the data input and output operations of the SoC. To address the thermal challenges posed by the identified thermal hotspot regions in both the GPU and certain CPU cores, thermal conductive TSVs, such as the thermal conductive TSVs 252a discussed above may be incorporated into the SoC package. By integrating these thermal conductive TSVs into the SoC structure, heat produced in the thermal hotspot regions can be effectively routed away from the sensitive components, ensuring enhanced heat dissipation. Together with the thermal conductive TSVs 252a, the power/signal TSVs 252b provide power and/or signal transmission among the IC dies. The thermal conductive TSVs 252a may outnumber the power/signal TSVs 252b in some embodiments. In the depicted embodiment, one or more power/signal TSVs 252b may be surrounded by a subset of the thermal conductive TSVs 252a.

The implementation of thermal conductive TSVs and power/signal TSVs extending from a backside of the semiconductor device not only promotes improved thermal performance (particularly at the backside of the semiconductor device), preventing potential overheating, but also aids in prolonging the device's lifespan and maintaining its operational efficiency.

In one example aspect, the present disclosure provides an embodiment of a method. The method includes receiving a workpiece including a device layer disposed on a first side of the workpiece, forming a first interconnect structure over the device layer, attaching a substrate over the first interconnect structure, etching from a second side of the workpiece to form at least one first trench and at least one second trench, the first trench extending partially into the substrate for a first distance, the second trench extending partially into the substrate for a second distance, and the first distance being smaller than the second distance, forming a first conductive feature in the first trench and a second conductive feature in the second trench, forming a second interconnect structure over the first conductive feature and the second conductive feature, and thinning the substrate from the first side of the workpiece to expose the second conductive feature, the first conductive feature remaining partially embedded in the substrate. In some embodiments, the first trench includes a first trench width, the second trench includes a second trench width, and the first trench width is smaller than the second trench width. In some embodiments, the first trench and the second trench are formed simultaneously. In some embodiments, the first trench and the second trench are formed separately. In some embodiments, the forming of the second interconnect structure includes prior to the forming of the first trench and the second trench, forming a first portion of the second interconnect structure, and after the forming of the first conductive feature and the second conductive feature, forming a second portion of the second interconnect structure, the second portion of the second interconnect structure covering the first conductive feature and the second conductive feature. In some embodiments, the forming of the second interconnect structure includes after the forming of the first conductive feature, forming a first portion of the second interconnect structure, and after the forming of the second conductive feature, forming a second portion of the second interconnect structure, the first and second portions of the second interconnect structure covering the first conductive feature, and the second portion of the second interconnect structure covering the second conductive feature. In some embodiments, each of the first and second trenches extends through the device layer and the first interconnect structure. In some embodiments, the first conductive feature is configured to dissipate heat from the device layer, and the second conductive feature is configured to transmit power or signal. In some embodiments, the workpiece is a first workpiece, and the method further includes bonding a second workpiece to the first side of the first workpiece, the second conductive feature electrically connecting to circuitries formed in the second workpiece. In some embodiments, the substrate is a carrier wafer.

In another example aspect, the present disclosure provides an embodiment of a method. The method includes forming a workpiece including a device layer located at a frontside of the workpiece and a substrate located at a backside of the workpiece, forming a frontside interconnect structure over the device layer, forming a heat dissipation layer over the frontside interconnect structure, in a top view of the workpiece the heat dissipation layer including a plurality of openings, forming a semiconductor layer over the heat dissipation layer, etching from the backside of the workpiece to form first trenches and second trenches. The first trenches extend through the device layer and the frontside interconnect structure and stop at the heat dissipation layer, and the second trenches extend through the device layer, the frontside interconnect structure, and the openings in the heat dissipation layer, and partially into the semiconductor layer. The method also includes forming a plurality of first vias in the first trenches and a plurality of second vias in the second trenches, forming a backside interconnect structure under the device layer, and thinning the semiconductor layer to expose the second vias. In some embodiments, the method also includes prior to the etching from the backside of the workpiece, thinning the substrate from the backside of the workpiece. In some embodiments, the first vias have a height less than the second vias. In some embodiments, the first vias have first ends located at the backside of the workpiece, the second vias have second ends located at the backside of the workpiece, and the first ends and the second ends are level. In some embodiments, the first vias have first ends located at the backside of the workpiece, the second vias have second ends located at the backside of the workpiece, and the first ends and the second ends are not level. In some embodiments, in the top view of the workpiece, the second vias are free of physical contact with the heat dissipation layer.

In yet another example aspect, the present disclosure provides an embodiment of a semiconductor device. The semiconductor device includes a device layer including transistors, a frontside interconnect structure disposed on the device layer and electrically coupled to the transistors, a semiconductor layer disposed on the frontside interconnect structure, a backside interconnect structure disposed under the device layer and electrically coupled to the transistors, a plurality of first vias extending through the device layer and the frontside interconnect structure, the first vias being covered by the semiconductor layer, and a plurality of second vias extending through the device layer, the frontside interconnect structure, and the semiconductor layer. In some embodiments, the first vias are partially embedded in the semiconductor layer. In some embodiments, the second vias are partially embedded in the backside interconnect structure. In some embodiments, the first vias have a width smaller than the second vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece including a device layer disposed on a first side of the workpiece;
forming a first interconnect structure over the device layer;
attaching a substrate over the first interconnect structure;
etching from a second side of the workpiece to form at least one first trench and at least one second trench, wherein the first trench extends partially into the substrate for a first distance, the second trench extends partially into the substrate for a second distance, and the first distance is smaller than the second distance;
forming a first conductive feature in the first trench and a second conductive feature in the second trench;
forming a second interconnect structure over the first conductive feature and the second conductive feature; and
thinning the substrate from the first side of the workpiece to expose the second conductive feature, wherein the first conductive feature remains partially embedded in the substrate.

2. The method of claim 1, wherein the first trench includes a first trench width, the second trench includes a second trench width, and the first trench width is smaller than the second trench width.

3. The method of claim 1, wherein the first trench and the second trench are formed simultaneously.

4. The method of claim 1, wherein the first trench and the second trench are formed separately.

5. The method of claim 1, wherein the forming of the second interconnect structure includes:
prior to the forming of the first trench and the second trench, forming a first portion of the second interconnect structure; and
after the forming of the first conductive feature and the second conductive feature, forming a second portion of the second interconnect structure, wherein the second portion of the second interconnect structure covers the first conductive feature and the second conductive feature.

6. The method of claim 1, wherein the forming of the second interconnect structure includes:
after the forming of the first conductive feature, forming a first portion of the second interconnect structure; and
after the forming of the second conductive feature, forming a second portion of the second interconnect structure, wherein the first and second portions of the second interconnect structure cover the first conductive feature, and the second portion of the second interconnect structure covers the second conductive feature.

7. The method of claim 1, wherein each of the first and second trenches extends through the device layer and the first interconnect structure.

8. The method of claim 1, wherein the first conductive feature is configured to dissipate heat from the device layer, and the second conductive feature is configured to transmit power or signal.

9. The method of claim 1, wherein the workpiece is a first workpiece, the method further comprising:
bonding a second workpiece to the first side of the first workpiece, wherein the second conductive feature electrically connects to circuitries formed in the second workpiece.

10. The method of claim 1, wherein the substrate is a carrier wafer.

11. A method, comprising:
forming a workpiece including a device layer located at a frontside of the workpiece and a substrate located at a backside of the workpiece;
forming a frontside interconnect structure over the device layer;
forming a heat dissipation layer over the frontside interconnect structure, wherein in a top view of the workpiece, the heat dissipation layer includes a plurality of openings;
forming a semiconductor layer over the heat dissipation layer;
etching from the backside of the workpiece to form a plurality of first trenches and a plurality of second trenches, wherein the first trenches extend through the device layer and the frontside interconnect structure and stop at the heat dissipation layer, and the second trenches extend through the device layer, the frontside interconnect structure, and the openings in the heat dissipation layer, and partially into the semiconductor layer;
forming a plurality of first vias in the first trenches and a plurality of second vias in the second trenches;
forming a backside interconnect structure under the device layer; and
thinning the semiconductor layer to expose the second vias.

12. The method of claim 11, further comprising:
prior to the etching from the backside of the workpiece, thinning the substrate from the backside of the workpiece.

13. The method of claim 11, wherein the first vias have a height less than the second vias.

14. The method of claim 11, wherein the first vias have first ends located at the backside of the workpiece, the second vias have second ends located at the backside of the workpiece, and the first ends and the second ends are level.

15. The method of claim 11, wherein the first vias have first ends located at the backside of the workpiece, the second vias have second ends located at the backside of the workpiece, and the first ends and the second ends are not level.

16. The method of claim 11, wherein in the top view of the workpiece, the second vias are free of physical contact with the heat dissipation layer.

17. A semiconductor device, comprising:
a device layer including transistors;
a frontside interconnect structure disposed on the device layer and electrically coupled to the transistors;
a semiconductor layer disposed on the frontside interconnect structure;
a backside interconnect structure disposed under the device layer and electrically coupled to the transistors;
a plurality of first vias extending through the device layer and the frontside interconnect structure, wherein the first vias are covered by the semiconductor layer; and
a plurality of second vias extending through the device layer, the frontside interconnect structure, and the semiconductor layer.

18. The semiconductor device of claim 17, wherein the first vias are partially embedded in the semiconductor layer.

19. The semiconductor device of claim 17, wherein the second vias are partially embedded in the backside interconnect structure.

20. The semiconductor device of claim 17, wherein the first vias have a width smaller than the second vias.
